(19) United States
(12) Patent Application Publication
(10) Pub. No.: US 2024/0414964 A1
(43) Pub. Date: Dec. 12, 2024

(54) DISPLAY SUBSTRATE AND METHOD FOR MANUFACTURING SAME, AND DISPLAY DEVICE

(71) Applicants: Yunnan Invensight Optoelectronics Technology Co., Ltd., Kunming (CN); BOE Technology Group Co., Ltd., Beijing (CN)

(72) Inventors: Zongshun YANG, Beijing (CN); Hongtao YU, Beijing (CN); Dongdong SU, Beijing (CN); Yunhao ZHANG, Beijing (CN); Zhongxiang YU, Beijing (CN); Jianming ZOU, Beijing (CN); Fushuang ZHANG, Beijing (CN); Chao YANG, Beijing (CN); Kuanta HUANG, Beijing (CN); Shengji YANG, Beijing (CN); Xiaochuan CHEN, Beijing (CN)

(21) Appl. No.: 18/696,961

(22) PCT Filed: Jul. 31, 2023
(86) PCT No.: PCT/CN2023/110095

§ 371 Date: Mar. 28, 2024

(30) Foreign Application Priority Data
Aug. 17, 2022 (CN) 202210986153.2

(51) Int. Cl. H10K 59/131; H10K 59/12; H10K 59/122

(52) U.S. Cl. CPC H10K 59/131; H10K 59/1201; H10K 59/122

(57) ABSTRACT

Provided is a display substrate. The display substrate includes a first conductive layer including the first electrode corresponding to each of the light-emitting components; a plurality of organic functional material layers, each of the organic functional material layers including one organic functional layer corresponding to each of the light-emitting components; at least one second conductive layer, each second conductive layer including the connection electrode corresponding to each of the light-emitting components; and a pixel definition layer including retaining walls and accommodating parts, one accommodating part being arranged corresponding to one first electrode; wherein the retaining wall is provided with a groove; an opening size of the groove proximal to the base substrate is not smaller than an opening size of the groove distal to the base substrate; and the groove at least disconnects the second conductive layer formed thereon to form the connection electrodes.

### CROSS-REFERENCE TO RELATED APPLICATION

This application is a U.S. national stage of international application No. PCT/CN2023/110095, filed on Jul. 31, 2023, which claims priority to Chinese Patent Application No. 2022109861532, filed on Aug. 17, 2022, and entitled “DISPLAY SUBSTRATE, PREPARATION METHOD THEREOF AND DISPLAY EQUIPMENT”, the disclosures of which are herein incorporated by reference in their entireties.

### TECHNICAL FIELD

The present disclosure belongs to the field of display technologies, and in particular, relates to a display substrate, a method for manufacturing the same, and a display device.

### BACKGROUND

Due to a small size and ultrahigh pixels per inch (PPI), a microdisplay substrate is easy to cause the cross color of adjacent light-emitting components in a display substrate, thereby affecting color purity and color gamut of the display product, and seriously causing the display product to show a low grayscale.

### SUMMARY

Some embodiments of the present disclosure provide a display substrate. The display substrate includes a base substrate, and a plurality of light-emitting components arranged on the base substrate, wherein the light-emitting component includes a first electrode, a plurality of organic functional layers, at least one connection electrode, and a second electrode along a direction distal to the base substrate; the first electrode is disposed on a side of the plurality of organic functional layers proximal to the base substrate; the second electrode is disposed on a side of the plurality of organic functional layers distal to the base substrate; the organic functional layers adjacently arranged are connected through the connection electrode; wherein,
the display substrate includes:
a first conductive layer, including the first electrode corresponding to each of the light-emitting components;
a plurality of organic functional material layers, each of the organic functional material layers including one organic functional layer corresponding to each of the light-emitting components;
at least one second conductive layer, each second conductive layer including the connection electrode corresponding to each of the light-emitting components; and
a pixel definition layer, including retaining walls and accommodating parts, one accommodating part being arranged corresponding to one first electrode; wherein the retaining wall is provided with a groove; an opening size of the groove proximal to the base substrate is not smaller than an opening size of the groove distal to the base substrate, and the groove at least disconnects the second conductive layer formed thereon to form the connection electrodes.

In some embodiments, the groove penetrates through the retaining wall along a thickness direction of the base substrate, and the opening size of the groove monotonically increases along a direction proximal to the base substrate.

In some embodiments, an angle between a sidewall of the groove and a side surface of the base substrate proximal to the first conductive layer ranges from 250 to 35°.

In some embodiments, a sidewall of the groove includes a first side edge distal to the base substrate and a second side edge proximal to the base substrate; and a width between orthographic projections of the first side edge and the second side edge on the base substrate ranges from 0.05 μm to 0.12 μm.

In some embodiments, a filling structure is filled between the first electrodes adjacently arranged; and a surface of the filling structure distal to the base substrate is flush with a surface of the first electrode distal to the base substrate.

In some embodiments, the filling structure is made of silicon oxide.

In some embodiments, the organic functional layer includes at least one light-emitting layer and a sub-functional layer, the sub-functional layer including at least one of an electron injection layer, an electron transport layer, an electron blocking layer, a hole blocking layer, a hole transport layer, and a hole injection layer.

In some embodiments, the display substrate further includes a color film layer arranged on a side of the light-emitting component distal to the base substrate.

Some embodiments of the present disclosure further include a method for manufacturing a display substrate. The method is configured to manufacture the display substrate according to any of the above embodiments. The method for manufacturing the display substrate includes the following steps:
forming a base substrate; and
forming a plurality of light-emitting components on the base substrate; wherein the light-emitting component includes a first electrode, a plurality of organic functional layers, at least one connection electrode, and a second electrode along a direction distal to the base substrate; the first electrode is disposed on a side of the plurality of organic functional layers proximal to the base substrate, and the second electrode is disposed on a side of the plurality of organic functional layers distal to the base substrate; the organic functional layers adjacently arranged are connected through the connection electrode;
said forming the plurality of light-emitting components on the base substrate includes:
forming a first conductive layer on the base substrate, the first conductive layer including the first electrode corresponding to each of the light-emitting components;
forming a pixel definition layer on a side of the first conductive layer distal to the base substrate, the pixel definition layer including retaining walls and accommodating parts, and one accommodating part being arranged corresponding to one first electrode; wherein the retaining wall is provided with a groove; an opening size of the groove proximal to the base substrate is not smaller than an opening size of the groove distal to the base substrate;
forming a plurality of organic functional material layers and second conductive layers on a side of the pixel definition layer distal to the base substrate; wherein each of the organic functional material layers includes the organic functional layer corresponding to each of the light-emitting components; each of the second conductive layers includes the connection electrode corresponding to each of the light-emitting components; the groove at least disconnects the second conductive layer formed thereon to form the connection electrodes; and
forming a third conductive layer on a side of the plurality of organic functional material layers distal to the base substrate, the third conductive layer being reused as the second electrode corresponding to each of the light-emitting components.

In some embodiments, said forming the first conductive layer on the base substrate includes:
forming the first electrode corresponding to each of the light-emitting components on the base substrate, and forming a filling structure between the adjacent first electrodes, a surface of the filling structure distal to the base substrate being flush with a surface of the first electrode distal to the base substrate;
said forming the pixel definition layer on the side of the first conductive layer distal to the base substrate includes:
forming a pixel definition pattern on the side of the first conductive layer distal to the base substrate, the pixel definition pattern including defining structures and accommodating parts; and
forming a groove on the defining structure to form the retaining wall with the groove.

In some embodiments, after the plurality of light-emitting components are formed on the base substrate, the method further includes:
forming an encapsulation layer on the side of the plurality of light-emitting components distal to the base substrate;
forming a planarization layer on a side of the encapsulation layer distal to the base substrate; and
forming a color film layer on a side of the planarization layer distal to the base substrate.

Some embodiments of the present disclosure further provide a display device, wherein the display device includes the display substrate according to any of the above embodiments.

### BRIEF DESCRIPTION OF THE DRAWINGS

FIG. 1 is a schematic structural diagram of a common OLED structure in the related art;

FIG. 2 is a film layer diagram of a display substrate according to some embodiments of the present disclosure;

FIG. 3 is a schematic diagram of film layers of a light-emitting component according to some embodiments of the present disclosure;

FIG. 4 is a schematic structural diagram of a groove according to some embodiments of the present disclosure;

FIG. 5 is a schematic structural diagram of a first conductive layer provided with a filling structure according to some embodiments of the present disclosure;

FIG. 6 is a specific film layer diagram of a display substrate according to some embodiments of the present disclosure;

FIGS. 7a to 7e are schematic diagrams showing a method for manufacturing a display substrate according to some embodiments of the present disclosure; and

FIGS. 8a to 8h are schematic diagrams showing the manufacturing process of some film layers of a display substrate according to some embodiments of the present disclosure.

Reference numerals in the drawings are as follows: a display substrate 100; a base substrate 10; a first electrode 21; an organic functional layer 22; a connection electrode 23; a second electrode 24; a first conductive layer 1; an organic functional material layer 2; a second conductive layer 3; a pixel definition layer 4; a retaining wall 41; an accommodating part 42; a groove 43; an electron injection layer EIL; a first electron transport layer ETL1; a second electron transport layer ETL2; an electron blocking layer EBL; a hole blocking layer HBL; a first hole transport layer HTL1; a second hole transport layer HTL2; a first hole injection layer HIL1; a second hole injection layer HIL2; an organic light-emitting layer R-EML corresponding to a red pixel; an organic light-emitting layer G-EML corresponding to a green pixel; an organic light-emitting layer B-EML corresponding to a blue pixel; a filling structure 11; a first inorganic encapsulation layer EPL2; an organic encapsulation layer EPL2; a second inorganic encapsulation layer EPL3; a planarization layer PLN; a color film layer CF; a red filter R-CF; a green filter G-CF; a blue filter B-CF; a pixel definition pattern 40; and a defining structure 44.

### DETAILED DESCRIPTION

For clearer descriptions of the objectives, technical solutions, and advantages of the embodiments of the present disclosure, the technical solutions in the embodiments of the present disclosure are clearly and completely described below with reference to the accompanying drawings of the embodiments of the present disclosure. Apparently, the described embodiments are merely some embodiments of the present disclosure, rather than all of the embodiments. Components of the embodiments of the present disclosure that are generally described and illustrated in the accompanying drawings herein may be arranged and designed in a variety of different configurations. Therefore, the following detailed description of the embodiments of the present disclosure provided by the accompanying drawings is not intended to limit the scope of the present disclosure as claimed, but merely represents selected embodiments of the present disclosure. All other embodiments obtained by those skilled in the art through the embodiments of the present disclosure without making creative efforts shall fall within the protection scope of the present disclosure.

Unless otherwise defined, technical or scientific terms used in the present disclosure should have the ordinary meanings as understood by those of ordinary skill in the art to which the present disclosure belongs. The terms “first”, “second”, and other similar words, as used in the present disclosure, do not indicate any order, quantity, or importance, but are merely defined to distinguish different components. Likewise, the terms “a”, “an”, “the”, or other similar words do not indicate a limitation of quantity, but rather the presence of at least one. The terms “include”, “comprise”, or other similar words mean that the elements or objects stated before them encompass the elements or objects and equivalents thereof listed after them, but do not exclude other elements or objects. The terms “connecting”, “connected”, or other similar words are not limited to physical or mechanical connections, but may include electrical connections, whether direct or indirect. The terms “up”, “down”, “left”, “right”, and the like are merely defined to indicate relative positional relationships. In the case that the absolute position of a described object changes, the relative positional relationships may also change accordingly.

The mentioned term “a plurality of or several” in the present disclosure means two or more. The term “and/or” describes the association relationship of the associated objects, and indicates that three relationships may be present. For example, A and/or B may indicate that: only A is present, both A and B are present, and only B is present. The symbol “/” generally indicates an “or” relationship between the associated objects.

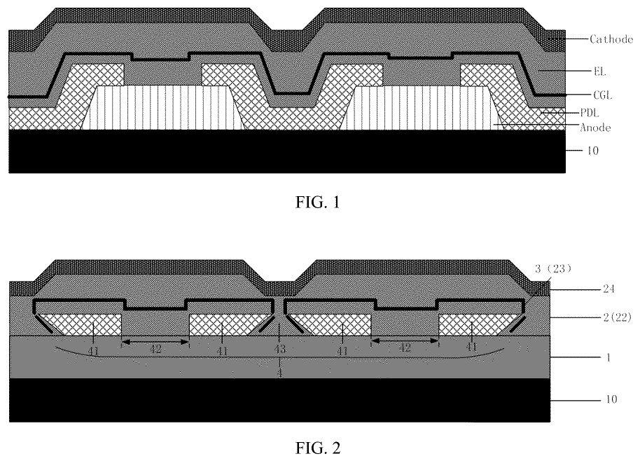

FIG. 1 is a structural schematic diagram of a common organic light-emitting diode (OLED) in the related art. As shown in FIG. 1, a charge generation layer (CGL) is an important connection layer of an upper light-emitting layer and a lower light-emitting layer. Under the condition that a whole layer of a pixel definition layer (PDL) is evaporated with a functional film layer (EL) and light-emitting components are connected in series, the charge generation layer (CGL) has a strong capability of transversely transmitting signals, such that a signal transmission path exists between adjacent light-emitting components, causing problems such as serious cross color of the display substrate.

Some embodiments of the present disclosure provide a display substrate. FIG. 2 is a film layer plate diagram of the display substrate according to some embodiments of the present disclosure. As shown in FIG. 2, a display substrate 100 includes a base substrate 10 and a plurality of light-emitting components arranged on the base substrate 10. The light-emitting component includes a first electrode 21, a plurality of organic functional layers 22, at least one connection electrode 23 and a second electrode 24 along the direction distal to the base substrate; the first electrode 21 is disposed on a side of the plurality of organic functional layers 22 proximal to the base substrate, and the second electrode 24 is disposed on a side of the plurality of organic functional layers 22 distal to the base substrate; and the organic functional layers 22 disposed adjacently are connected through the connection electrode 23.

Here, the polarity of the first electrode 21 is opposite to that of the second electrode 22. According to the embodiments of the present disclosure, the first electrode 21 is an anode and the second electrode 22 is a cathode as an example for description. The organic functional layers 22 adjacently arranged refer to the organic functional layers 22 stacked along a direction pointing from the first electrode 21 toward the second electrode 24.

It should be noted that the display substrate 100 according to the embodiments of the present disclosure is mainly applied to a micro display substrate. For example, a micro OLED display substrate is manufactured by evaporating a whole layer of an organic material in a manufacturing process. A light-emitting component is a micro OLED device. As a charge generation layer CGL (that is, the second conductive layer 3 described below) has a strong capability of transversely transmitting signals, and a distance between adjacent first electrodes 21 is close (for example, 0.5 μm-1.0 μm), evaporating a whole layer of an organic material may cause signal crosstalk between adjacent light-emitting components, resulting in problems such as serious cross color of the display substrate. Based on this, on the premise of evaporating a whole layer of an organic material, the display substrate according to the present disclosure uses the pixel definition layer to partition the charge generation layer CGL, to form an independent connection electrode of each of the light-emitting components.

Specifically, as shown in FIG. 2, the display substrate 100 includes a first conductive layer 1, a plurality of organic functional material layers 2, at least one second conductive layer 3, and a pixel definition layer 4. The first conductive layer 1 includes a first electrode 21 corresponding to each of the light-emitting components. Each organic functional material layer 2 includes an organic functional layer 22 corresponding to each of the light-emitting components. Each second conductive layer 3 includes a connection electrode 23 corresponding to each of the light-emitting components. The pixel definition layer 4 includes retaining walls 41 and accommodating parts 42. One accommodating part 42 is arranged corresponding to one first electrode 21; wherein the retaining wall 41 is provided with a groove 43; an opening size of the groove 43 proximal to the base substrate 10 is not smaller than an opening size distal to the base substrate 10; and the groove 43 at least can disconnect the second conductive layer 3 formed thereon to form each of the connection electrodes 23.

Here, the second conductive layer 3 is the charge generation layer CGL. The pixel definition layer 4 is configured to define the position of the organic functional layer 22 of each of the light-emitting components.

In the display substrate 100 according to the embodiments of the present disclosure, the retaining wall 41 in the pixel definition layer 4 is provided with the groove 43. In the case that a whole layer of the organic material is evaporated, the charge generation layer CGL can be at least partitioned by using a feature that an opening size of the groove 43 proximal to the base substrate 10 is not smaller than the opening size distal to the base substrate 10, and a falling of a sidewall of the groove 43, to further form each connection electrode 23. Moreover, each of the light-emitting components is provided with an independent connection electrode 23, which can avoid signal crosstalk between adjacent light-emitting components, and further solve problems such as color purity, color gamut, and a low gray scale influenced by the signal crosstalk.

In some embodiments, the organic functional layer 22 includes at least one light-emitting layer EML and a sub-functional layer; the sub-functional layer includes at least one of an electron injection layer EIL, an electron transport layer ETL, an electron blocking layer EBL, a hole blocking layer HBL, a hole transport layer HTL, and a hole injection layer HIL.

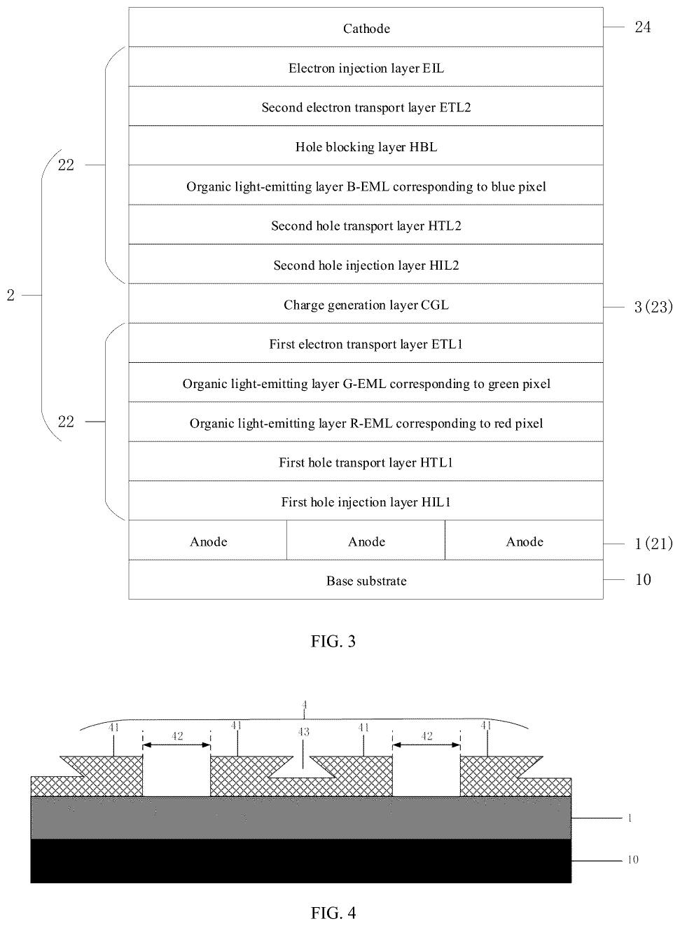

FIG. 3 is a schematic diagram of a film layer of a light-emitting component according to some embodiments of the present disclosure. As shown in FIG. 3, it only shows a schematic diagram of a film layer of three light-emitting components connected in series, one light-emitting component including a first electrode 21, two organic functional layers 22, at least one connection electrode 23, and a second electrode 24 along a direction away from the base substrate 10. For example, one of the two organic functional layers 22 that is proximal to the first electrode 21 (that is, an anode) includes a first hole injection layer HIL1, a first hole transport layer HTL1, an organic light-emitting layer R-EML corresponding to a red pixel, an organic light-emitting layer G-EML corresponding to a green pixel, and a first electron transport layer ETL1, which are sequentially arranged on the first conductive layer 1 and on the side distal to the base substrate 10; a second conductive layer 3 (that is, a charge generation layer CGL) is arranged on the side of the first electron transport layer ETL1 distal to the base substrate 10; and the other of the two functional layers 22 that is proximal to the second electrode 24 (that is, a cathode) further includes a second hole injection layer HIL2, a second hole transport layer HTL2, an organic light-emitting layer B-EML corresponding to a blue pixel, a hole blocking layer HBL, a second electron transport layer ETL2, and an electron injection layer EIL, which are sequentially arranged on the side of the second conductive layer 3 distal to the base substrate 10.

Here, the organic light-emitting layer R-EML corresponding to the red pixel emits red light; the organic light-emitting layer G-EML corresponding to the green pixel emits green light; the organic light-emitting layer B-EML corresponding to the blue pixel emits blue light; and the organic light-emitting layer R-EML corresponding to the red pixel, and the organic light-emitting layer G-EML corresponding to the green pixel and the organic light-emitting layer B-EML corresponding to the blue pixel jointly act to enable the light-emitting components to emit light of various colors.

It should be noted that in the embodiments of the present disclosure, the organic functional layer may be arranged according to an actual material of the organic functional layer in the light-emitting component. For example, in addition to a position structure of each organic functional layer 22 shown in FIG. 2, it may also be determined whether to remove the electron injection layer EIL, the second electron transport layer ETL2, and the hole blocking layer HBL that are proximal to the second electrode 24 according to an influence of the actual material; and/or, it is determined whether to remove the second hole transport layer HTL2 and the second hole injection layer HIL2 between the organic light-emitting layer B-EML corresponding to the blue pixel and the organic light-emitting layer G-EML corresponding to the green pixel; and/or, it is determined whether to remove the first hole injection layer HIL1 and the first hole transport layer HTL1 that are proximal to the first electrodes 21. In addition, based on the actual material, it may also be determined whether the electron blocking layer EBL needs to be arranged between the first hole transport layer HTL1 and the organic light-emitting layer R-EML corresponding to the red pixel. The above adjustment process may be set according to actual experiences, and is not specifically limited in the embodiments of the present disclosure.

In some embodiments, as shown in FIG. 2, the groove 43 penetrates through the retaining wall 41 along a thickness direction of the base substrate 10, and the opening size of the groove 43 monotonically increases along the direction proximal to the base substrate 10. Here, the groove 43 penetrating through the retaining wall 41 is formed. The charge generation layer CGL can be at least partitioned by using a falling of the thickness of the entire retaining wall 41 and a sharp corner of the retaining wall 41 defined by the opening size of the groove 43, which avoids signal crosstalk between light-emitting components, and further solves problems such as color purity, color gamut, and a low gray scale influenced by the signal crosstalk.

In some embodiments, as shown in FIG. 2, an angle between a sidewall of the groove 43 and a side surface of the base substrate 10 proximal to the first conductive layer 1 ranges from 25° to 35°. It should also be understood that an angle between the sidewall of the groove 43 and a surface of the retaining wall 41 distal to the base substrate 10 ranges from 25° to 35°. Generally, a dihedral angle between the surface of the retaining wall 41 distal to the base substrate 10 and the sidewall of the retaining wall 41 (that is, the sidewall of the groove) is a smooth transition angle, such as a round angle or a flat chamfer angle, the angle between the sidewall of the groove 43 and the side surface of the base substrate 10 proximal to the first conductive layer 1 is used to further define the angle between the sidewall of the groove 43 and the surface of the retaining wall 41 distal to the substrate 10, which can at least partition the second conductive layer 3 formed on the side of the groove 43 distal to the base substrate 10, to form a connection electrode 23 of each of the light-emitting components.

In addition, the partition effect is also associated with the depth of the groove 43. The angle between the sidewall of the groove 43 and the side surface of the base substrate 10 proximal to the first conductive layer 1 is kept between 25° and 35°. The deeper the depth of the groove 43 is, the better the partition effect of the retaining wall 41 on the second conductive layer 3 is, the larger the number of layers of the film layers (including each stacked film layer in the organic functional layer 22) partitioned along a direction pointing the first electrode 21 toward the second electrode 24 is. It should be noted that, however, it should be ensured that the second electrode 24 cannot be partitioned by the partition effect corresponding to the depth of the groove 43, thereby avoiding the problems of poor encapsulation effect, display influence, and the like.

The depth of the groove 43 is set to at least partition the second conductive layer 3 and remains unchanged. Then, in the case that the angle between the sidewall of the groove 43 and the side of the base substrate 10 proximal to the first conductive layer 1 ranges from 25° to 35°, the smaller the angle between the sidewall of the groove 43 and the side of the base substrate 10 proximal to the first conductive layer 1 is, the better the partition effect of the retaining wall on the second conductive layer 3 is, the larger the number of layers of the film layers (including each stacked sub-functional layer in the organic functional layer 22) partitioned along a direction pointing from the first electrode 21 toward the second electrode 24. It should be noted that, however, it should be ensured that the second electrode 24 cannot be partitioned by the partition effect corresponding to the angle between the sidewall of the groove 43 and the side surface of the base substrate 10 proximal to the first conductive layer 1, thereby avoiding the problems of poor encapsulation effect, display influence, etc.

In some embodiments, FIG. 4 is a schematic structural diagram of another groove according to some embodiments of the present disclosure. As shown in FIG. 4, the groove 43 does not penetrate through the retaining wall 41 in a direction pointing from the second electrode 24 toward the first electrode 21. For example, in the manufacturing process, according to the requirement of the opening size of the groove 43, the retaining wall 41 is partially etched along the direction pointing from the second electrode 24 toward the first electrode 21, to acquire the groove 43 shown in FIG. 4. Here, the opening size of the groove 43 monotonically increases along the direction proximal to the base substrate 10. Specifically, the condition of partitioning the second conductive layer 3 can be satisfied by a joint action of the angle between the sidewall of the groove 43 and the side surface of the base substrate 10 proximal to the first conductive layer 1 and the depth of the groove 43.

In some embodiments, a sidewall of the groove 43 includes a first side edge distal to the base substrate 10 and a second side edge proximal to the base substrate 10. A width between orthographic projections of the first side edge and the second side edge on the base substrate 10 ranges from 0.05 μm to 0.12 μm. Here, to make the retaining wall 41 satisfy the condition of partitioning the second conductive layer 3, it requires the joint action of the angle between the sidewall of the groove 43 and the side surface of the base substrate 10 proximal to the first conductive layer 1 and/or the depth of the groove 43.

For example, an angle between the sidewall of the groove 43 and the side surface of the base substrate 10 proximal to the first conductive layer 1 is 30°. The width between orthographic projections of the first side edge and the second side edge on the base substrate 10 is 0.1 μm, which can satisfy the condition of partitioning the second conductive layer 3.

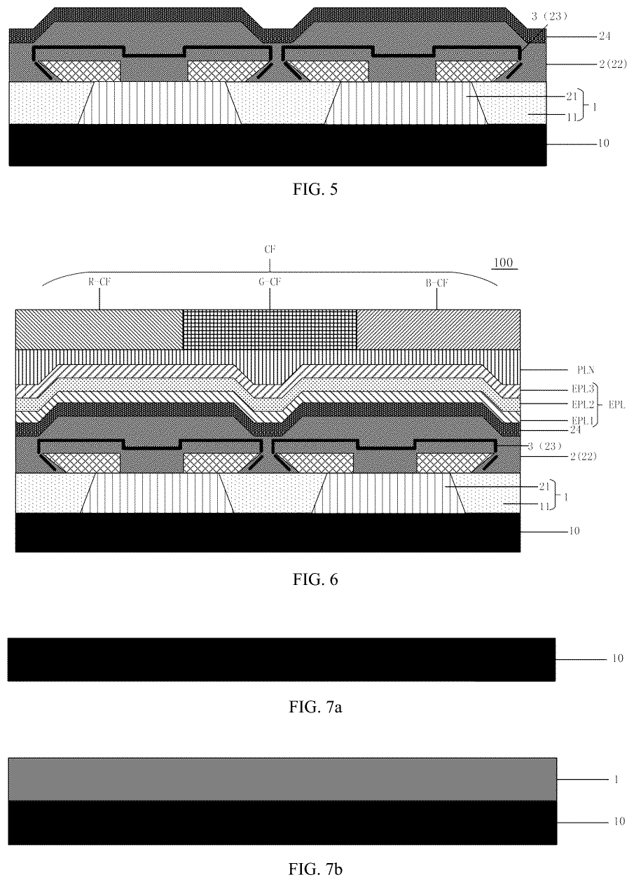

In some embodiments, FIG. 5 is a schematic structural diagram of a first conductive layer provided with a filling structure according to some embodiments of the present disclosure. As shown in FIG. 5, a filling structure 11 is filled between the first electrodes 21 adjacently arranged. A surface of the filling structure 11 distal to the base substrate 10 is flush with the surface of the first electrode 21 distal to the base substrate 10, such that insulation between the first electrodes 21 adjacently arranged can be better achieved, and planarization of the first conductive layer 1 is achieved, which is beneficial to the manufacturing of the pixel definition layer 4.

Here, as insulation is required between adjacent first electrodes 21, the filling structure 11 is made of an insulating material, and may be specifically silicon oxide (SiO).

In some embodiments, the retaining wall 41 is provided with a first region opposite to the first electrode 21 and a second region opposite to a structure (that is, the filling structure 11) except the first electrode 21 in the first conductive layer 1. The width of the first region ranges from 0.45 μm to 0.55 μm.

In some embodiments, a width between first side edges of two sidewalls of the groove 43 ranges from 0.43 μm to 0.50 μm.

In some embodiments, FIG. 6 is a specific film layer plate diagram of a display substrate according to some embodiments of the present disclosure. As shown in FIG. 6, the display substrate 100 further includes an encapsulation layer EPL, a planarization layer PLN, and a color film layer CF sequentially arranged on a side of the second electrode 24 of the light-emitting component distal to the base substrate 10. The planarization layer PLN is configured to form the color film layer CF on a plane film layer, to prevent the color film layer from being wrinkled and influencing the display effect of the display substrate 100. The encapsulation layer is configured to package the light-emitting component, to prevent each film layer in the light-emitting component from being corroded by external water and oxygen. The color film layer CF includes a red filter R-CF, a green filter G-CF and a blue filter B-CF.

Here, the encapsulation layer EPL includes a first inorganic encapsulation layer EPL2, an organic encapsulation layer EPL2, and a second inorganic encapsulation layer EPL3. For example, the inorganic encapsulation layer EPL is made of an insulating material such as silicon oxynitride (SiON), silicon oxide (SiOx), silicon nitride (SiNx), or a polymer resin. Inorganic materials such as silicon oxynitride (SiON), silicon oxide (SiOx), and silicon nitride (SiNx) have high compactness and can prevent intrusion of water, oxygen, and the like. A material of the organic encapsulation layer EPL2 is a polymer material containing a desiccant, a polymer material that blocks moisture, or the like, such as a polymer resin, to planarize the surface of the display substrate. Moreover, it may relieve the stress of the first inorganic encapsulation layer EPL2 and the second inorganic encapsulation layer EPL3, and may further include a water-absorbing material such as a desiccant to absorb substances such as water, oxygen, and the like that intrude into the inside.

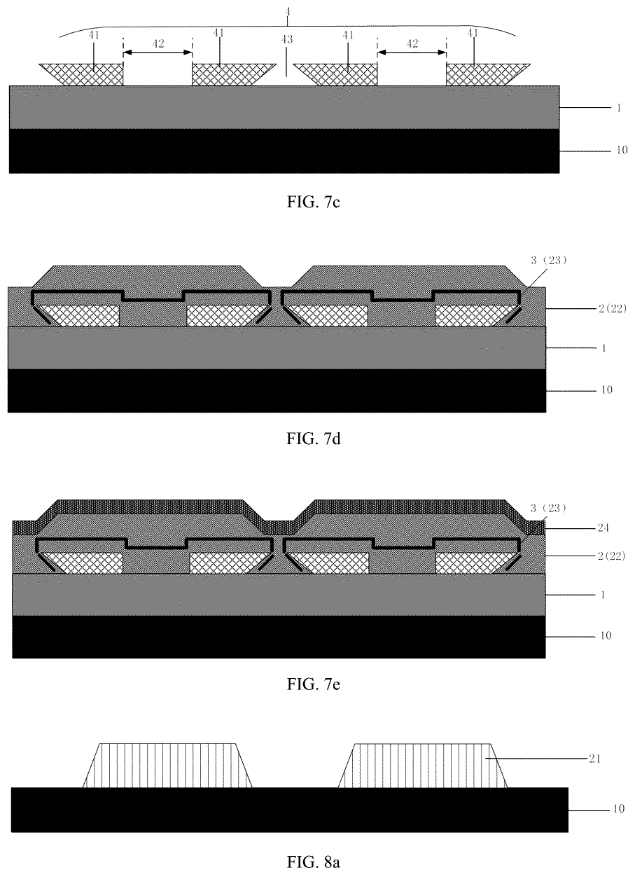

Based on the same inventive concept, some embodiments of the present disclosure further provide a method for manufacturing a display substrate 100. FIGS. 7a to 7e are flowcharts of a method for manufacturing a display substrate according to some embodiments of the present disclosure. As shown in FIGS. 7a to 7e, the method is mainly configured to manufacture the display substrate 100 according to any of the above embodiments. The method includes the following steps:
S11, as shown in FIG. 7a, the base substrate 10 is formed; and
S12, a plurality of light-emitting components on the base substrate 10 are formed.

Here, the light-emitting component includes a first electrode 21, a plurality of organic functional layers 22, at least one connection electrode 23, and a second electrode 24 along the direction distal to the base substrate 10; wherein the first electrode 21 is disposed on a side of the plurality of organic functional layers 22 proximal to the base substrate 10, and the second electrode 24 is disposed on a side of the plurality of organic functional layers 22 distal to the base substrate 10; and the organic functional layers 22 disposed adjacently are connected through the connection electrode 23.

In view of S12, the plurality of light-emitting components on the base substrate 10 are formed by S121 to S124:
S121, as shown in FIG. 7b, a first conductive layer 1 is formed on the base substrate 10.

Here, the first conductive layer 1 includes a first electrode 21 corresponding to each of the light-emitting components. According to the embodiments of the present disclosure, the first electrode 21 is an anode as an example for description.

Specifically, a conductive material is deposited on the base substrate 10. The first electrode corresponding to each of the light-emitting components is formed by using an etching process. Each first electrode 21 is disposed on the first conductive layer 1.

S122, as shown in FIG. 7c, a pixel definition layer 4 is formed on the side of the first conductive layer 1 distal to the base substrate 10.

The pixel definition layer 4 includes retaining walls 41 and accommodating parts 42, accommodating parts 42 correspond to the first electrodes 21 in one-to-one correspondence; wherein the retaining wall 41 is provided with a groove 43; an opening size of the groove 43 proximal to the base substrate 10 is not smaller than an opening size distal to the base substrate 10.

Specifically, a pixel defining material layer is deposited on the first conductive layer 1. The accommodating parts 42 and the retaining walls 41 are formed using an etching process. Specifically, etching may be performed twice. The pixel defining material layer is etched once to form the accommodating part 42, and the groove 43 is formed through the other etching.

With respect to etching the pixel defining material layer to form the accommodating part 42, specifically, the side of the pixel defining material layer distal to the base substrate 10 is coated with a photoresist. Exposure and development are performed using a mask plate, and the developed pixel defining material layer is etched using a dry etching process to form the accommodating part 42.

With respect to etching the pixel defining material layer to form the groove 43, specifically, the pixel defining material layer according to the embodiments of the present disclosure is a composite film layer structure, for example, silicon nitride (SiN) 600 and silicon oxide (SiO) 200 are sequentially arranged on the side of the first conductive layer 1 distal to the base substrate 10, wherein an etching rate of the SiN 600 is faster than that of the SiO 200. Thus, the SiN 600 on a lower layer forms an undercutting structure faster, and then forms the groove 43 together with the undercutting structure formed by the SiO 200. For example, the side of the pixel defining material layer distal to the base substrate 10 is coated with a photoresist. Exposure and development is performed using a mask plate, and the developed pixel defining material layer is etched using a dry etching process. The SiN 600 on a lower layer forms an undercutting structure faster, thus forming the groove 43 together with the undercutting structure formed by the SiO 200.

In the embodiments of the present disclosure, with a feature that an opening size of the groove 43 proximal to the base substrate 10 is not smaller than the opening size distal to the base substrate 10, and a falling of a sidewall of the groove 43, the second conductive layer 3 can be at least partitioned, thus forming each connection electrode 23. Moreover, each of the light-emitting components is provided with an independent connection electrode 23, which can avoid signal crosstalk between light-emitting components, and further solve problems such as color purity, color gamut, and a low gray scale influenced by the signal crosstalk. Meanwhile, in the embodiments of the present disclosure, the second conductive layer 3 is partitioned by etching the pixel definition layer 4 again to form the groove 43 only based on the original manufacturing process, so it is not necessary to add another partition structure on the film layer for partitioning the second conductive layer 3, thereby simplifying the manufacturing process and improving the manufacturing efficiency of the display substrate 100.

S123, as shown in FIG. 7d, a plurality of organic functional material layers 2 and second conductive layers 3 are formed on the side of the pixel definition layer 4 distal to the base substrate 10.

Each organic functional material layer 2 includes an organic functional layer 22 corresponding to each of the light-emitting components; each second conductive layer 3 includes a connection electrode 23 corresponding to each of the light-emitting components; and the groove 43 at least can disconnect the second conductive layer 3 formed thereon to form each of the connection electrodes 23.

Specifically, the organic functional layers 22 and the second conductive layer 3 shown in FIG. 3 are taken as an example. First, a first hole injection layer HIL1, a first hole transport layer BTL1, an organic light-emitting layer R-EML corresponding to a red pixel, an organic light-emitting layer G-EML corresponding to a green pixel, and a first electron transport layer ETL1 are sequentially formed on the side of the pixel definition layer 4 distal to the base substrate 10; a second conductive layer 3 is formed on the side of the first electron transport layer ETL1 distal to the base substrate 10; and a second hole injection layer HIL2, a second hole transport layer HTL2, an organic light-emitting layer B-EML corresponding to a blue pixel, a hole blocking layer HBL, a second electron transport layer ETL2, and an electron injection layer EIL are sequentially formed on the side of the second conductive layer 3 distal to the base substrate 10.

The grooves 43 at least can disconnect the second conductive layers 3 formed thereon, which means that they can also disconnect the first hole injection layer HIL1, the first hole transport layer HTL1, the organic light-emitting layer R-EML corresponding to the red pixel, the organic light-emitting layer G-EML corresponding to the green pixel, and the first electron transport layer ETL1. Whether to disconnect at least one of the second hole injection layer HIL2, the second hole transport layer HTL2, the organic light-emitting layer B-EML corresponding to the blue pixel, the hole blocking layer HBL, the second electron transport layer ETL2, and the electron injection layer EIL, depends on an angle between the sidewall of the groove and the side surface of the base substrate 10 proximal to the first conductive layer 1, a width between orthographic projections of the first side edge and the second side edge on the base substrate 10 within 0.05 μm and 0.12 μm, the depth of the groove 43, and the like.

It should be noted that whether the organic functional layer 22 is disconnected has no influence on the display of the display substrate 100.

S124, as shown in FIG. 7e, a third conductive layer is formed on the side of the plurality of organic functional material layers 2 distal to the base substrate 10; and the third conductive layer is reused as the second electrode 24 corresponding to each of the light-emitting components.

According to the embodiments of the present disclosure, the second electrode 24 is a cathode as an example for description.

It should be noted that, it should be ensured that the second electrode 24 cannot be partitioned by the partition effect of the groove 43, thereby avoiding the problems of poor encapsulation effect, display influence, etc.

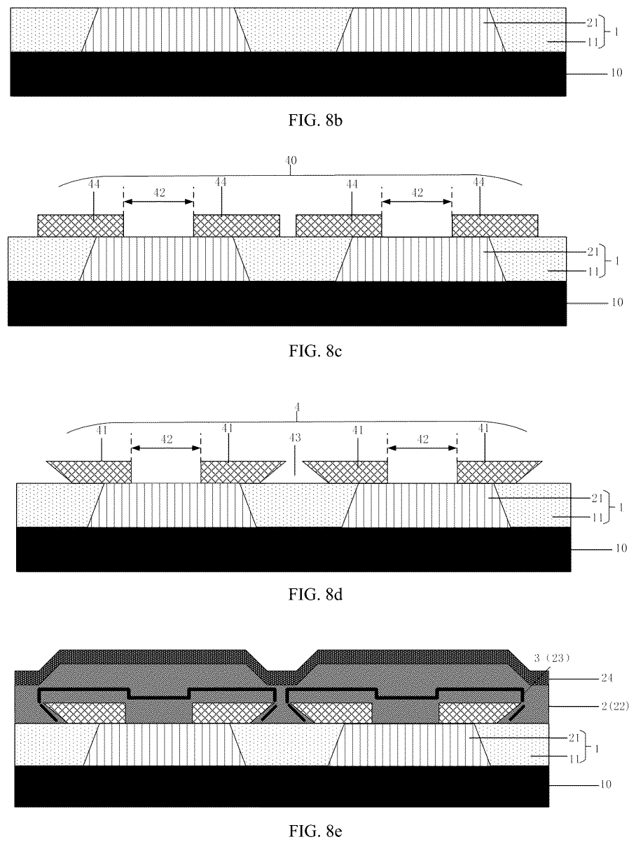

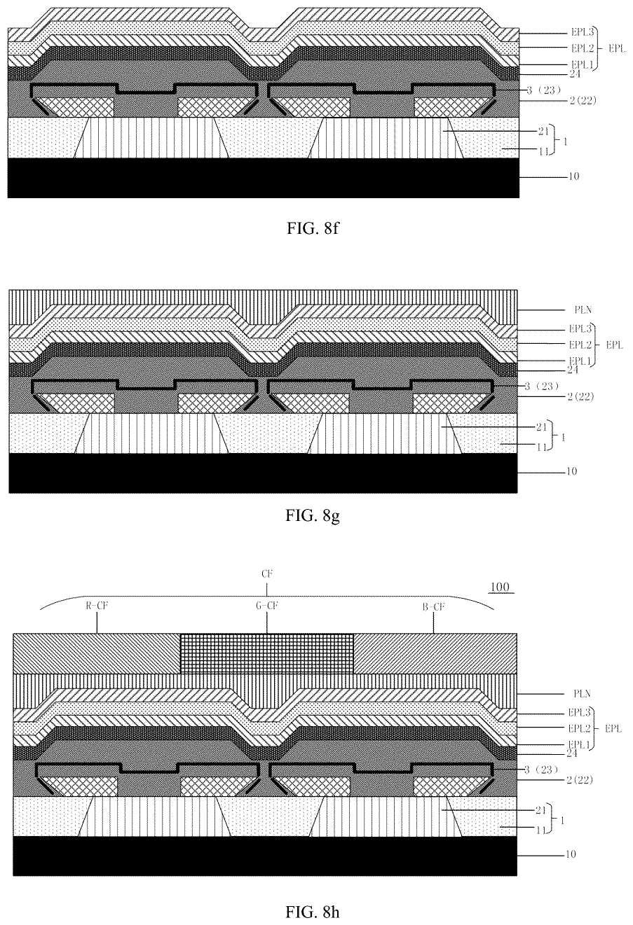

In some embodiments, FIGS. 8a to 8h are flowcharts for manufacturing some film layers of a display substrate according to some embodiments of the present disclosure, as shown in FIGS. 8a to 8h.

In view of S121, the first conductive layer 1 is formed on the base substrate 10, as shown in FIGS. 8a and 8b. As shown in FIG. 8a, the first electrode 21 corresponding to each of the light-emitting components is formed on the base substrate 10. As shown in FIG. 8b, a filling structure 11 is formed between adjacent first electrodes 21.

A surface of the filling structure 11 distal to the base substrate 10 is flush with a surface of the first electrode 21 distal to the base substrate 10.

In view of S121, the pixel definition layer 4 is formed on the side of the first conductive layer 1 distal to the base substrate 10, as shown in FIGS. 8c and 8d. As shown in FIG. 8c, a pixel definition pattern 40 is formed on the side of the first conductive layer 1 distal to the base substrate 10. The pixel definition pattern 40 includes defining structures 44 and accommodating parts 42.

Specifically, first, a pixel defining material layer is formed on the side of the first conductive layer 1 distal to the base substrate 10; then, the side of the pixel defining material layer distal to the base substrate 10 is coated with a photoresist, exposure and development are performed by using a mask plate, and the developed pixel defining material layer is etched using a dry etching process to form the accommodating parts 42 and acquire the pixel definition pattern 40.

As shown in FIG. 8d, a groove 43 is formed on the defining structure 44 to form a retaining wall 41 with the groove 43.

The pixel defining material layer according to the embodiments of the present disclosure may be a composite film layer structure, for example, silicon nitride SiN 600 and silicon oxide SiO 200 are sequentially arranged on the side of the first conductive layer 1 distal to the base substrate 10, wherein an etching rate of the SiN 600 is faster than that of the SiO 200.

The mask plate is designed according to the angle between the sidewall of the groove 43 and the side surface of the base substrate 10 proximal to the first conductive layer 1, and the width between orthographic projections of the first side edge and the second side edge on the base substrate 10. The side of the pixel defining material layer distal to the base substrate 10 is coated with a photoresist. Exposure and development are conducted through a preset mask plate to change the performance of a part of the pixel defining material layer. Then, the developed pixel defining material layer is etched using a dry etching process. The SiN 600 on a lower layer forms an undercutting structure faster, thus forming the groove 43 together with the undercutting structure formed by the SiO 200.

As shown in FIG. 8e, an organic light-emitting material layer 2, a second conductive layer 3 and a third conductive layer (that is, the second electrode 24) are formed on the side of the pixel definition layer 4 distal to the base substrate 10.

As shown in FIG. 8f, an encapsulation layer EPL is formed on the side of the plurality of light-emitting components distal to the base substrate 10. The encapsulation layer EPL includes a first inorganic encapsulation layer EPL2, an organic encapsulation layer EPL2, and a second inorganic encapsulation layer EPL3.

As shown in FIG. 8g, a planarization layer PLN is formed on the side of the encapsulation layer EPL distal to the base substrate 10.

As shown in FIG. 8h, a color film layer CF is formed on the side of the planarization layer PLN distal to the base substrate 10. The color film layer CF includes a red filter R-CF, a green filter G-CF and a blue filter B-CF.

Based on the same inventive concept, some embodiments of the present disclosure further provide a display device, wherein the display device includes the display substrate 100 according to any of the above embodiments. The display device may include, for example, a cell phone, a tablet computer, a wearable device, and an in-vehicle device.

It should be understood that the above embodiments are merely exemplary embodiments employed to illustrate the principles of the present disclosure, and the present disclosure is not limited thereto. It will be apparent to those of ordinary skill in the art that various changes and modifications can be made without departing from the spirit and scope of the present disclosure, and these changes and modifications are also considered to fall within the protection scope of the present disclosure.

1. A display substrate, comprising: a base substrate, and a plurality of light-emitting components arranged on the base substrate, wherein each light-emitting component comprises a first electrode, a plurality of organic functional layers, at least one connection electrode, and a second electrode along a direction distal to the base substrate; the first electrode is disposed on a side of the plurality of organic functional layers proximal to the base substrate, and the second electrode is disposed on a side of the plurality of organic functional layers distal to the base substrate; the organic functional layers adjacently arranged are connected through the connection electrode; wherein,
the display substrate comprises:
a first conductive layer, comprising the first electrode corresponding to each of the light-emitting components;
a plurality of organic functional material layers, each of the organic functional material layers comprising one organic functional layer corresponding to each of the light-emitting components;
at least one second conductive layer, each second conductive layer comprising the connection electrode corresponding to each of the light-emitting components; and
a pixel definition layer, comprising retaining walls and accommodating parts, one accommodating part being arranged corresponding to one first electrode; wherein the retaining wall is provided with a groove; an opening size of the groove proximal to the base substrate is not smaller than an opening size of the groove distal to the base substrate; and the groove at least disconnects the second conductive layer formed thereon to form the connection electrodes.

2. The display substrate according to claim 1, wherein the groove penetrates through the retaining wall along a thickness direction of the base substrate, and the opening size of the groove monotonically increases along a direction proximal to the base substrate.

3. The display substrate according to claim 1, wherein an angle between a sidewall of the groove and a side surface of the base substrate proximal to the first conductive layer ranges from 25° to 35°.

4. The display substrate according to claim 1, wherein a sidewall of the groove comprises a first side edge distal to the base substrate and a second side edge proximal to the base substrate; and a width between orthographic projections of the first side edge and the second side edge on the base substrate ranges from 0.05 μm to 0.12 μm.

5. The display substrate according to claim 1, wherein a filling structure is filled between the first electrodes adjacently arranged; and a surface of the filling structure distal to the base substrate is flush with a surface of the first electrode distal to the base substrate.

6. The display substrate according to claim 5, wherein the filling structure is made of silicon oxide.

7. The display substrate according to claim 1, wherein the organic functional layer comprises at least one light-emitting layer and a sub-functional layer, the sub-functional layer comprising at least one of an electron injection layer, an electron transport layer, an electron blocking layer, a hole blocking layer, a hole transport layer, and a hole injection layer.

8. The display substrate according to claim 1, wherein the display substrate further comprises a color film layer arranged on a side of the light-emitting component distal to the base substrate.

9. A method for manufacturing a display substrate, wherein the method comprises:
forming a base substrate; and
forming a plurality of light-emitting components on the base substrate; wherein the light-emitting component comprises a first electrode, a plurality of organic functional layers, at least one connection electrode, and a second electrode along a direction distal to the base substrate; the first electrode is disposed on a side of the plurality of organic functional layers proximal to the base substrate, and the second electrode is disposed on a side of the plurality of organic functional layers distal to the base substrate; the organic functional layers adjacently arranged are connected through the connection electrode;
said forming the plurality of light-emitting components on the base substrate comprises:
forming a first conductive layer on the base substrate, the first conductive layer comprising the first electrode corresponding to each of the light-emitting components;
forming a pixel definition layer on a side of the first conductive layer distal to the base substrate, the pixel definition layer comprising retaining walls and accommodating parts, and one accommodating part being arranged corresponding to one first electrode; wherein the retaining wall is provided with a groove; an opening size of the groove proximal to the base substrate is not smaller than an opening size of the groove distal to the base substrate;
forming a plurality of organic functional material layers and second conductive layers on a side of the pixel definition layer distal to the base substrate; wherein each of the organic functional material layers comprises the organic functional layer corresponding to each of the light-emitting components; each of the second conductive layers comprises the connection electrode corresponding to each of the light-emitting components; the groove at least disconnects the second conductive layer formed thereon to form the connection electrodes; and
forming a third conductive layer on a side of the plurality of organic functional material layers distal to the base substrate, the third conductive layer being reused as the second electrode corresponding to each of the light-emitting components.

10. The method according to claim 9, wherein said forming the first conductive layer on the base substrate comprises:
forming the first electrode corresponding to each of the light-emitting components on the base substrate, and forming a filling structure between the adjacent first electrodes, a surface of the filling structure distal to the base substrate being flush with a surface of the first electrode distal to the base substrate;
said forming the pixel definition layer on the side of the first conductive layer distal to the base substrate comprises:
forming a pixel definition pattern on the side of the first conductive layer distal to the base substrate, the pixel definition pattern comprising defining structures and accommodating parts; and
forming a groove on the defining structure to form the retaining wall with the groove.

11. The method according to claim 9, wherein after the plurality of light-emitting components are formed on the base substrate, the method further comprises:
forming an encapsulation layer on the side of the plurality of light-emitting components distal to the base substrate;
forming a planarization layer on a side of the encapsulation layer distal to the base substrate; and
forming a color film layer on a side of the planarization layer distal to the base substrate.

12. A display device, comprising a display substrate, wherein the display substrate comprises:
a base substrate, and a plurality of light-emitting components arranged on the base substrate, wherein each light-emitting component comprises a first electrode, a plurality of organic functional layers, at least one connection electrode, and a second electrode along a direction distal to the base substrate; the first electrode is disposed on a side of the plurality of organic functional layers proximal to the base substrate, and the second electrode is disposed on a side of the plurality of organic functional layers distal to the base substrate; the organic functional layers adjacently arranged are connected through the connection electrode; wherein,
the display substrate comprises:
a first conductive layer, comprising the first electrode corresponding to each of the light-emitting components;
a plurality of organic functional material layers, each of the organic functional material layers comprising one organic functional layer corresponding to each of the light-emitting components;
at least one second conductive layer, each second conductive layer comprising the connection electrode corresponding to each of the light-emitting components; and
a pixel definition layer, comprising retaining walls and accommodating parts, one accommodating part being arranged corresponding to one first electrode; wherein the retaining wall is provided with a groove; an opening size of the groove proximal to the base substrate is not smaller than an opening size of the groove distal to the base substrate; and the groove at least disconnects the second conductive layer formed thereon to form the connection electrodes.

13. The display device according to claim 12, wherein the groove penetrates through the retaining wall along a thickness direction of the base substrate, and the opening size of the groove monotonically increases along a direction proximal to the base substrate.

14. The display device according to claim 12, wherein an angle between a sidewall of the groove and a side surface of the base substrate proximal to the first conductive layer ranges from 25° to 35°.

15. The display device according to claim 12, wherein a sidewall of the groove comprises a first side edge distal to the base substrate and a second side edge proximal to the base substrate; and a width between orthographic projections of the first side edge and the second side edge on the base substrate ranges from 0.05 μm to 0.12 μm.

16. The display device according to claim 12, wherein a filling structure is filled between the first electrodes adjacently arranged; and a surface of the filling structure distal to the base substrate is flush with a surface of the first electrode distal to the base substrate.

17. The display device according to claim 16, wherein the filling structure is made of silicon oxide.

18. The display device according to claim 12, wherein the organic functional layer comprises at least one light-emitting layer and a sub-functional layer, the sub-functional layer comprising at least one of an electron injection layer, an electron transport layer, an electron blocking layer, a hole blocking layer, a hole transport layer, and a hole injection layer.

19. The display device according to claim 12, wherein the display substrate further comprises a color film layer arranged on a side of the light-emitting component distal to the base substrate.
